(19) United States
(12) Patent Application Publication
(10) Pub. No.: US 2004/0207417 A1
(43) Pub. Date: Oct. 21, 2004

(54) Electronic probe with positionable tip

(76) Inventor: Andrew Harvey Barr, Roseville, CA (US)

Correspondence Address: HEWLETT-PACKARD DEVELOPMENT COMPANY, Intellectual Property Administration, P.O. Box 272400, Fort Collins, CO, 80627-2400, US

(21) Appl. No.: 10/417,848

(22) Filed: Apr. 16, 2003

(51) Int. Cl. G01R 31/02

(52) U.S. Cl. 324/754

(57) ABSTRACT

An electronic probe includes a body and a tip positionable relative to the body. With such a positionable tip, a technician can more easily probe a region of a circuit board that is otherwise difficult to access with a conventional probe, and can do so without using an extension wire. Furthermore, the tip may be removable and include a point for contacting a signal node and a coupling element that couples the point to the body and that allows the point to assume multiple positions relative to the body.

### BACKGROUND OF THE INVENTION

Many electronic devices, such as computers and stereos, include a main circuit board, or motherboard, that contains the device's basic circuitry and/or components for operating the device. For example, a main circuit board may include a microprocessor for executing instructions, memory for storing data, and an expansion slot for adding more components or circuitry to the main board. In addition, many electronic devices include a secondary circuit board, or daughterboard, that may be mounted to the expansion slot of the main circuit board and that contains additional circuitry and/or components for operating the device. For example, a daughterboard may include memory for storing data, and a microprocessor for executing instructions to operate a portion of the device such as a modem incorporated in a computer or an equalizer incorporated in a stereo.

When such devices malfunction or when the design or manufacture of such devices is not complete, a technician typically tests/diagnosis the device by probing the circuits and/or components of the main and/or secondary circuit boards with a probe coupled to a measuring device such as an oscilloscope.

Unfortunately, probing a circuit board can be difficult with many probes. Manufacturers frequently mount circuit boards close together and/or close to the housing of the device to reduce the overall size of the device. This reduces the space between the circuit boards and/or circuit board and housing in which a technician can maneuver a probe. Consequently, some regions of a circuit board may be difficult or impossible for a technician to probe.

For example, FIG. 1 is a view of an electronic system 10 and a conventional high-frequency-signal probe 12 that a technician may use to probe the system 10. The system 10 includes two secondary circuit boards 14 and 16 mounted to a main circuit board 18. The secondary board 14 includes a probe pad 20, and a component 22 having a terminal 24. The probe 12 is connected to a cable 26 that couples the probe to an oscilloscope (not shown), and includes a body 28 and a tip 30 for probing the pad 20 and terminal 24.

To probe the secondary circuit board 14, a technician tries to contact the pad 20 or terminal 24 with the probe tip 30. To do this, the technician attempts to angle the probe 12 such that the tip 30 contacts the pad 20 or terminal 24. But if the boards 14 and 16 are too close together, or if the probe body 28 is too wide, then the technician may be unable to angle the probe 12 to the degree necessary for the tip 30 to contact the pad 20 or terminal 24.

One solution to this problem is to solder an extension wire (not shown) between the pad 20 or terminal 24 and the tip 30. Although such an extension wire allows a technician to more easily access the board 14, the extension wire may present other problems. For example, the extension wire may add inductance to the measurement path, and thus, may corrupt the accuracy of the measurement, particularly where the probed signal has a high frequency.

Another solution is to remove the board 16 so as to allow easier access to the board 14. But this solution may be unavailable if the board 16 is needed for the proper operation of the circuits on the board 14, or if the probe 12 cannot be properly angled even with the board 16 removed.

### SUMMARY OF THE INVENTION

In one aspect of the invention, a signal probe includes a body and a tip positionable relative to the body. With such a positionable tip, a technician can more easily probe a region of a circuit board that is otherwise difficult to access with a conventional probe, and can do so without using an extension wire. Furthermore, the tip may be removable and include a point for contacting a signal node and a coupling element that couples the point to the body and that allows the point to assume multiple positions relative to the body.

### BRIEF DESCRIPTION OF THE DRAWINGS

FIG. 1 illustrates the difficulty of probing one of two circuit boards mounted close together with a conventional signal probe.

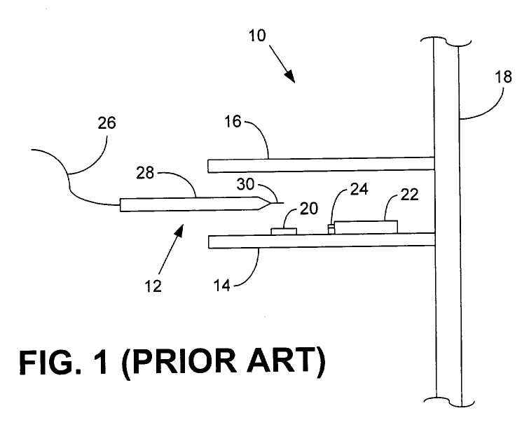

FIG. 2 is a view of a probe having a positionable tip according to an embodiment of the invention.

FIG. 3 is a perspective view of the probe in FIG. 2 according to an embodiment of the invention.

FIG. 4 is a perspective view of a signal probe according to another embodiment of the invention.

### DESCRIPTION OF THE PREFERRED EMBODIMENTS

The following discussion is presented to enable one skilled in the art to make and use the invention. Various modifications to the disclosed embodiments will be readily apparent to those skilled in the art, and the generic principles herein may be applied to other embodiments and applications without departing from the spirit and scope of the present invention as defined by the appended claims. Thus, the present invention is not intended to be limited to the embodiments shown, but is to be accorded the widest scope consistent with the principles and features disclosed herein.

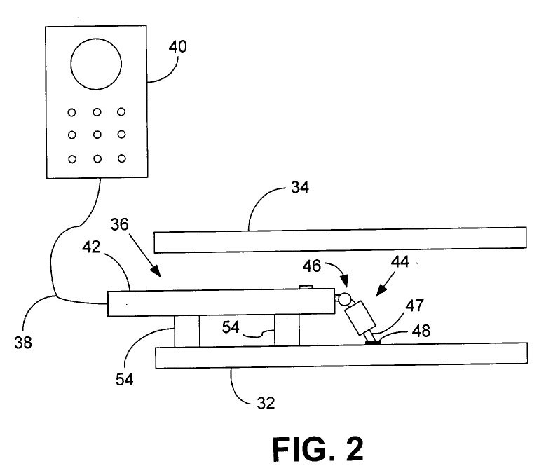

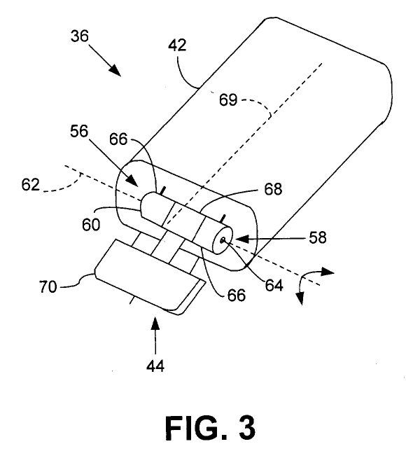

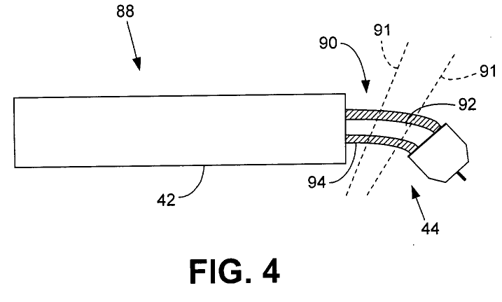

FIG. 2 is a view of two circuit boards 32 and 34 incorporated in an electronic device (not shown for clarity), and a signal probe 36 having a positionable tip 44 according to an embodiment of the invention. A cable 38 couples the probe 36 to an oscilliscope 40, which receives and displays the probed signal. The probe 36 may be an active probe, such as a high frequency probe that includes circuitry (not shown) within the probe body 42, or may be a passive probe. The tip 44 includes a coupling element 46 (discussed in greater detail in conjunction with FIGS. 3 and 4) that couples the tip 44 to the body 42 and allows the tip 44 to be positioned relative to the body 42. The tip 44 also includes a conductive point 47 for contacting the pad 48. With a positionable tip, the probe 36 may be used to probe a pad 48 of the circuit board 32 that would be difficult to access with a conventional probe. Thus, a technician may probe the pad 48 without an extension wire (not shown) and without removing the board 34. Furthermore, the tip 44, or portions thereof, may be removable and replaceable.

Still referring to FIG. 2, the tip 44 may include a locking element (not shown in FIG. 2 but discussed in greater detail in conjunction with FIG. 3) for retaining the tip 44 at one or more positions where the tip 44 is angled relative to the body 42. For example, the locking element may retain the tip 44 at three different angular positions. The first position may be where the tip 44 and body 42 are aligned, that is, form a 180° angle. The second position may be where the tip 44 and body 42 form a 135° angle. And the third position may be where the tip 44 and body 42 form a 90° angle. Alternatively, the locking element 46 may retain the tip 44 at more or fewer than three angular positions relative to the body 42.

Still referring to FIG. 2, supports 54 may be used to support the probe 36. By pivoting the tip 44, the supports 54 can hold the probe 42 substantially parallel to the board 32 while the tip contacts the probe pad 48. In this position, the supports 54 can securely support the probe 36 above other components (not shown) on the circuit board 32 so that a technician does not have to support the probe with his/her hand.

FIG. 3 is a perspective view of the probe 36 in FIG. 2 according to an embodiment of the invention. The tip 44 includes a coupling element 56 that couples the tip 44 to the body 42 and allows the tip 44 to be positioned relative to the body 42, and a locking element 58 for retaining the tip 44 at one or more positions relative to the body 42.

In one embodiment, the coupling element 56 includes a hinge 60 that allows the tip 44 to pivot about the hinge axis 62, and the locking element 58 includes a screw 64 for frictionally retaining the tip 44. The hinge 60 is a conventional hinge that includes a first section 66 fastened to the body 42 and a second section 68 fastened to a head 70 of the tip 44. The first section 66 is rotatably coupled to the second section 68 to allow the tip 44 to pivot about the hinge axis 62 when a technician wishes to position the tip 44 relative to the body 42. The screw 64 includes a contact surface (not shown) that may be forced against the second section 68 of the hinge 60 to retain the tip 44 at a desired position relative to the body 42. To move the screw 64 toward and away from the second section 68, the screw 64 includes a thread (not shown) that slidingly contacts a corresponding thread (not shown) in the first section 66.

In other embodiments, the tip 44 may include a coupling element that allows the tip 44 to rotate about more than one axis. For example, in addition to allowing the tip 44 to pivot about the pivot axis 62, the coupling element 56 may allow the tip 44 to rotate about a longitudinal axis 69 of the body 42 that is perpendicular to the pivot axis 62, and to be locked in a particular position. In addition, the tip 44 may include other locking elements such as a conventional ratchet and pawl that allows the tip 44 to pivot in one direction but prevents the tip 44 from pivoting in an opposite direction unless the pawl is moved away from the ratchet.

FIG. 4 is a perspective view of a probe 88 according to another embodiment of the invention. The probe 88 includes a coupling element 90 made of conventional material that plastically deforms when bent, i.e., retains its new shape. Thus, the tip 44 may be positioned about multiple and/or different axes 91 and may be retained in a position by the material's non-elasticity.

In one embodiment, the coupling element 90 includes a metal conductor 92 that electrically couples the body 42 to the tip 44 and a rubber sheath 94 made of conventional rubber for protecting and insulating the conductor 92. The conductor 92 may be made from any desired metal such as copper that is capable of bending. The coupling element 90 may be permanently attached to the tip 44 and the body 42 or releasably fastened to the tip 44 and/or the body 42. When releasably fastened to the tip 44 and/or body 42, the tip 44 may be replaced as desired. Furthermore, the coupling element 90 may include a cover (not shown) of conductive material such as copper mesh to shield the conductor 92 from signal noise. The cover may be located on the outside surface of the rubber sheath 94 and may be plastically and/or elastically deformable.

In other embodiments, the coupling element 90 may be made of conventional material that elastically deforms when bent. Thus, the tip 44 may bend about multiple axes 91. But because the material elastically deforms, the tip 44 typically is retained in a particular angular position relative to the body 42 by a technician or an external support pressing the tip 44 against the probed point such as the probe pad 48 of FIG. 2. Thus, in this embodiment the coupling element 98 does not retain the tip 44 in the angular position once this pressure is removed.

What is claimed is:

1. A signal-probe tip, comprising:
a conductive point operable to contact a signal node; and
a coupling element operable to couple the point to a probe body and to allow the point to assume multiple positions relative to the body.

2. The tip of claim 1 wherein the tip is releasably fastened to the body.

3. The tip of claim 1 wherein the tip is pivotable relative to the body.

4. The tip of claim 1 wherein the coupling element comprises a locking element operable to retain the tip at at least one position.

5. The tip of claim 1 wherein the coupling element comprises a hinge.

6. The tip of claim 1 wherein the coupling element comprises a hinge operable to pivot the tip about a pivot axis.

7. The tip of claim 1 wherein, after the coupling element is bent, the coupling element retains its new shape.

8. The tip of claim 1 wherein, the coupling element comprises a material operable to allow the tip to bend relative to the body by plastically deforming.

9. The tip of claim 1 wherein, after the coupling element is bent, the coupling element does not retain its new shape.

10. The tip of claim 1 wherein, the coupling element comprises a material operable to allow the tip to bend relative to the body by elastically deforming.

11. A signal probe comprising:
a body; and
a signal-probe tip that includes:
a conductive point operable to contact a signal node; and
a coupling element operable to couple the point to the body and to allow the point to assume multiple positions relative to the body.

12. The probe of claim 11 wherein the probe comprises a passive probe.

13. The probe of claim 11 wherein the probe comprises an active probe.

14. A method comprising:
positioning a tip of a probe relative to a body of the probe; and
contacting a signal source with the tip.

15. The method of claim 14 wherein positioning a tip includes bending the tip.

16. The method of claim 14 wherein positioning the tip includes pivoting a hinge.

17. The method of claim 14 further comprising retaining the tip in a position relative to the body by exerting pressure against the tip.
